(19) United States
(12) Patent Application Publication
(10) Pub. No.: US 2026/0338902 A1
(43) Pub. Date: Oct. 29, 2026

(54) METHODS AND SYSTEMS FOR MAGNETIC RESONANCE IMAGING

(71) Applicant: UNITED IMAGING HEALTHCARE NORTH AMERICA, INC., Houston, TX (US)

(72) Inventors: Qi LIU, Houston, TX (US); Zihao CHEN, Houston, TX (US)

(73) Assignee: UNITED IMAGING HEALTHCARE NORTH AMERICA, INC., Houston, TX (US)

(21) Appl. No.: 19/193,946

(22) Filed: Apr. 29, 2025

(51) Int. Cl. G01R 33/565; G01R 33/54; G01R 33/56

(52) U.S. Cl. CPC G01R 33/56509; G01R 33/543; G01R 33/5608

(57) ABSTRACT

The present disclosure provides a method and system for magnetic resonance imaging. The method for magnetic resonance imaging including: obtaining preliminary scanning data and navigation data of an imaging region of an imaging target; determining, based on the navigation data, temporal information relating to at least one temporal dimension of the imaging region; determining, based on the preliminary scanning data and the temporal information, spatial information related to at least one spatial dimension of the imaging region; and performing, based on the temporal information and the spatial information, a motion correction.

### TECHNICAL FIELD

The present disclosure is related to the field of medical imaging technology, and in particular to a method and a system for magnetic resonance imaging.

### BACKGROUND

Magnetic resonance imaging (MRI) is a non-invasive medical imaging technique that generates high-resolution images of structures in a body primarily by means of strong magnetic fields and radio frequency waves. An MRI device generates the magnetic field to align hydrogen nuclei (mainly hydrogen atoms in water molecules) in an imaging target body in a direction of the magnetic field. Then a radio-frequency (RF) pulse perturbs a spin of the hydrogen nucleus, causing the hydrogen nucleus to temporarily deviate from the direction of the magnetic field. When the RF pulse stops, the hydrogen nucleus returns to its original state and releases energy, which is received as a signal. Different tissues have different water contents and environments for the hydrogen atoms, causing them to recover at different rates (e.g., relaxation times T1, and T2), thus generating images with a tissue contrast.

When imaging some moving parts (e.g., an abdomen), as abdominal organs move up and down with a movement of a thorax during respiration, the periodic movement leads to artifacts in the imaging, affecting a clarity of the image. Particularly during a dynamic imaging, the respiration motion makes a balance between a high temporal resolution and a high spatial resolution more difficult.

Therefore, how to realize a high-quality dynamic imaging of moving parts in a free motion state is still an unsolved problem.

### SUMMARY

One or more embodiments of the present disclosure provides a method for magnetic resonance imaging. The method for magnetic resonance imaging includes: obtaining preliminary scanning data and navigation data of an imaging region of an imaging target; determining, based on the navigation data, temporal information relating to at least one temporal dimension of the imaging region; determining, based on the preliminary scanning data and the temporal information, spatial information related to at least one spatial dimension of the imaging region; and performing, based on the temporal information and the spatial information, a motion correction.

One or more embodiments of the present disclosure provide a system for magnetic resonance imaging including: at least one storage device including a set of instructions; and at least one processor in communication with the at least one storage device. When executing the set of instructions, the at least one processor is directed to perform operations including: obtaining preliminary scanning data and navigation data of an imaging region of an imaging target; determining, based on the navigation data, temporal information relating to at least one temporal dimension of the imaging region; determining, based on the preliminary scanning data and the temporal information, spatial information relating to at least one spatial dimension of the imaging region; and performing, based on the temporal information and the spatial information, a motion correction.

One or more embodiments of the present disclosure provide a method for magnetic resonance imaging comprising: obtaining preliminary scanning data of an imaging region of an imaging target; determining temporal information relating to at least one temporal dimension of the imaging region and spatial information relating to at least one spatial dimension of the imaging region; and performing, based on the preliminary scanning data, the temporal information, and the spatial information, a motion correction.

### BRIEF DESCRIPTION OF THE DRAWINGS

The present disclosure will be further illustrated by way of exemplary embodiments, which are described in detail by means of the accompanying drawings. These embodiments are not limiting, and in these embodiments, the same numbering denotes the same structure, wherein:

FIG. 1 is a schematic diagram illustrating an application scenario of a system for magnetic resonance imaging according to some embodiments of the present disclosure;

FIG. 2 is a flowchart illustrating an exemplary method for magnetic resonance imaging according to some embodiments of the present disclosure;

FIG. 3 is a flowchart illustrating an exemplary process for obtaining spatial information according to some embodiments of the present disclosure;

FIG. 4 is a flowchart illustrating an exemplary process for generating a reconstructed image according to some embodiments of the present disclosure;

FIG. 5 is a flowchart illustrating an exemplary process for determining a deformation field according to some embodiments of the present disclosure;

FIG. 6 is a flowchart illustrating an exemplary process for generating a reconstructed image according to some embodiments of the present disclosure;

FIG. 7 is a flowchart illustrating an exemplary process for obtaining training data of a second neural network according to some embodiments of the present disclosure; and

FIG. 8 is a modular diagram illustrating an exemplary system for magnetic resonance imaging according to some embodiments of the present disclosure.

### DETAILED DESCRIPTION

To more clearly illustrate the technical solutions of the embodiments of the present disclosure, the accompanying drawings required to be used in the description of the embodiments are briefly described below. Obviously, the accompanying drawings in the following description are only some examples or embodiments of the present disclosure, and it is possible for those skilled in the art to apply the present disclosure to other similar scenarios in accordance with these drawings without creative labor. Unless obviously obtained from the context or the context illustrates otherwise, the same numeral in the drawings refers to the same structure or operation.

It should be understood that the terms “system”, “device” “unit” and/or “module” as used herein, are used as a way to distinguish between different components, elements, parts, sections or assemblies at different levels. However, the words may be replaced by other expressions if other words accomplish the same purpose.

As shown in the present disclosure and in the claims, unless the context clearly suggests an exception, the words “a,” “one,” “an,” and/or “the” do not refer specifically to the singular but may also include the plural. Generally, the terms “including” and “comprising” suggest only the inclusion of clearly identified operations and elements. In general, the terms “including” and “comprising” only suggest the inclusion of explicitly identified operations and elements that do not constitute an exclusive list, and the method or apparatus may also include other operations or elements.

Flowcharts are used in the present disclosure to illustrate operations performed by a system according to embodiments of the present disclosure. It should be appreciated that the preceding or following operations are not necessarily performed in an exact sequence. Instead, operations may be processed in reverse order or simultaneously. Also, it is possible to add other operations to these processes or remove an operation or operations from them.

How to realize a free-breathing abdominal magnetic resonance dynamic imaging with a high image quality is a long-standing unresolved clinical challenge. Constrained by limitations of a dynamic time process after injection of a contrast agent and an effect of a respiration motion, it is often difficult to obtain an image with both a high spatial resolution and a high temporal resolution. For example, abdominal organs are constantly moving during a respiration period, which affects the image quality and generates artifacts; also, there is a contradiction in expecting to obtain both the high temporal resolution (e.g., to accurately record dynamic changes during the respiration period) and the high spatial resolution (e.g., to render details clearly), as a higher resolution requires more scanning time, which conflicts with a requirement to capture rapidly changing dynamic information. While the injection and a distribution of the contrast agent is a rapidly changing process over a short period of time, a temporal constraint makes it difficult for an imaging system to obtain continuous high-quality images.

Among the related techniques, applications using a Golden-angle Radial Sparse Parallel Imaging (GRASP) technique and its derivative XD-GRASP (extra-dimensional golden-angle radial sparse parallel), as well as a Multitasking technique for dynamic imaging of the abdomen in a free motion stage are proposed, which achieves some results.

GRASP-like techniques use a three-dimensional (3D) radial sampling with golden-angle sorting to divide continuously collected data into a plurality of stages (divisions) in a time direction, relying on a compressed sensing (CS) algorithm, which uses a total variation in the time direction, a better image quality is obtained at a high acceleration factor. XD-GRASP further extracts the motion stage from navigation signals and divides the data in both motion and temporal directions, relying on the CS algorithm, using a total variation in both the motion and temporal directions, the dynamic imaging with differentiated motion stages is realized. A core of GRASP-like technology is to use the CS algorithm to improve the image quality, and the following technical advantages are achieved: 1. the high image quality may be obtained, and the image appears to have small artifacts; 2. image details may be maintained well. However, there are still some technical disadvantages. 1. The acceleration factor is limited. When counts of the motion and a temporal groups are large, an amount of data per group is too small to save the image quality even with the CS algorithm. 2. A huge computational and memory consumption is required. The XD-GRASP needs to save all multidimensional images in the memory, resulting in a great demand for computational resource consumption. 3. A position mismatch between data of different motion dimensions, which results in a limited effect when applying a total variation.

A Multitasking technique uses a low-rank assumption to greatly simplify a problem by separating the problem to be solved into sub-problems of solving the time basis and space basis. The Multitasking technique includes a plurality of operations, where the first operation is performing a real-time reconstruction to obtain a real-time image. After that, the collected navigation signals are divided according to the motion and temporal dimensions to obtain an undersampled high-dimensional tensor, then a tensor complementation algorithm is used to obtain a complete high-dimensional tensor. Finally, a spatial basis is re-optimized using the complemented resampled time basis, and a regularization term for compressed sensing (e.g., the total variation acting on the spatial basis) is added to ultimately achieve a solution of a high-dimensional problem. A core of the technique is using a partially divisible low-rank model to achieve the high acceleration factor, as well as the using a spatial CS algorithm to enhance the image quality. Advantages of this technology are: 1. an ultra-high acceleration factor is achieved to obtain very high temporal and spatial resolutions; 2. relatively lower memory requirement is posed, which breaks a curse of dimensionality; 3. an ability to easily add other dimensions and contrasts. However, the technology also has some disadvantages. 1. A poor fidelity of the image details. For example, the spatial direction imposed by the total variation regularity term leads to abnormally high signals of blood vessels in the image before a liver augmentation. If the regularity term is not imposed, the image quality tends to be suboptimal, especially in an early period of artery. 2. Even after a rigid registration, the positions of the data in different respiration dimensions do not exactly match each other, and the low-rank property is limited.

In view of this, some embodiments of the present disclosure provide a method for magnetic resonance imaging (MRI). By using the Multitasking collection and the real-time reconstruction, real-time dynamic images with high image qualities and high time resolutions are obtained. Based on this, the non-rigid correction information (a deformation field) is obtained based on the real-time dynamic images, which in turn generates high-quality images by using the CS algorithm with temporal regularization.

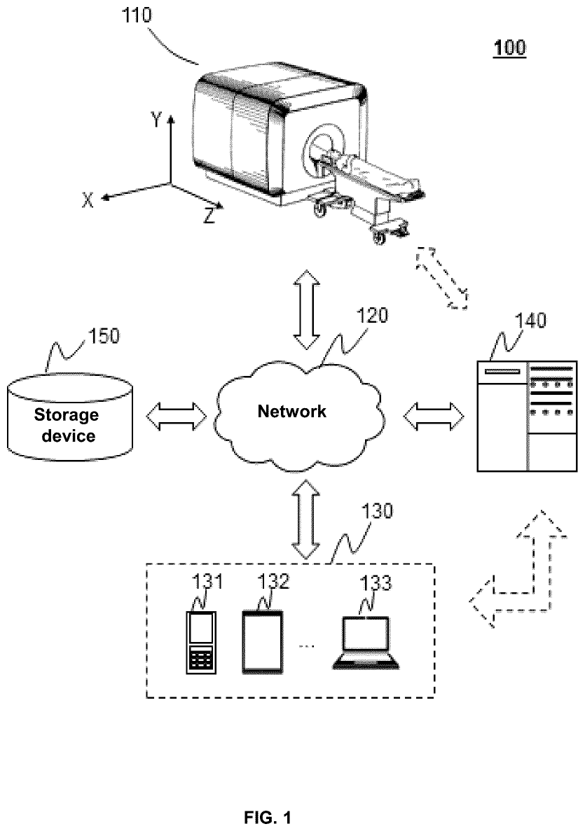

FIG. 1 is a schematic diagram illustrating an application scenario of a system for MRI according to some embodiments of the present disclosure;

As shown in FIG. 1, an application scenario 100 of the system for MRI may include an MRI scanner 110, a network 120, a terminal 130, a processing device 140, and a storage device 150. Components of the application scenario 100 of the system for MRI may be connected in various manners. Merely by way of example, the MRI scanner 110 is connected to the processing device 140 through the network 120. For another example, the MRI scanner 110 is directly connected to the processing device 140 (as shown by bidirectional arrows in dotted lines connecting the MRI scanner 110 to the processing device 140). For another example, the storage device 150 is connected to the processing device 140 either directly or through the network 120. For another example, a terminal device (e.g., terminal devices 131, 132, 133, etc.) is connected directly to processing device 140 (as shown by the bidirectional arrows in the dotted lines connecting the terminal 130 and the processing device 140) or through the network 120.

The MRI scanner 110 may be configured to scan an object (or a portion of the object) to obtain scanning data, e.g., MRI signals (also referred to as MR signals) associated with the object. For example, the MRI scanner 110 obtains a plurality of MRI signals by applying an MRI pulse sequence to the object. In this application, “object” and “body” are used interchangeably. Merely by way of example, the object includes a patient, an artificial object, etc. For another example, the object includes a particular portion, an organ and/or a tissue of the patient. For example, the object includes a head, a brain, a neck, a body, a shoulder, an arm, a chest, a heart, a stomach, a blood vessel, a soft tissue, a knee, a foot, etc., or any combination thereof. An abdominal imaging of the object in a free motion stage in the preceding section is for a purpose of example only, and technical solutions disclosed herein may also be applied to other parts of the body, e.g., imaging of a heart portion, etc.

An X-axis, a Y-axis and a Z-axis shown in FIG. 1 form an orthogonal coordinate system. The X-axis and Z-axis shown in FIG. 1 may be horizontal and the Y-axis may be vertical. As shown, a positive direction of the X-axis may be a direction from a right side to a left side of the MRI scanner 110 as viewed from facing a front of the MRI scanner 110; a positive direction of the Y-axis shown in FIG. 1 may be a direction from a lower portion to an upper portion of the MRI scanner 110; and a positive direction of the Z-axis shown in FIG. 1 may be a direction of a scanned object moving out of a scanning channel (or referred to as a hole) of the MRI scanner 110.

The network 120 may include any suitable network that facilitates an exchange of information and/or data for the application scenario 100 of the system for MRI. In some embodiments, one or more components of the application scenario 100 of the system for MRI (e.g., the MRI scanner 110, the terminal 130, the processing device 140, or the storage device 150) transmit the information and/or data with one or more other components of the application scenario 100 of the system for MRI through the network 120. For example, the processing device 140 obtains preliminary scanning data and navigation data from the MRI scanner 110 through the network 120. In some embodiments, the network 120 is a wired network or a wireless network, etc., or any combination thereof.

The terminal 130 includes the mobile device 131, a tablet 132, a laptop 133, etc., or any combination thereof. In some embodiments, the mobile device 131 includes a smart home device, a wearable device, a smart mobile device, a virtual reality device, an augmented reality device, etc., or any combination thereof. In some embodiments, the terminal 130 remotely operates the MRI scanner 110 and/or the processing device 140. In some embodiments, terminal 130 operates the MRI scanner 110 and/or the processing device 140 through a wireless connection. In some embodiments, the terminal 130 receives information and/or an instruction input by a user, and sends the information and/or the instruction to the MRI scanner or the processing device 140. In some embodiments, the terminal 130 receives the data and/or information from the processing device 140. In some embodiments, the terminal 130 is a portion of the processing device 140. In some embodiments, the terminal 130 is omitted.

The processing device 140 may process the data and/or information obtained from the MRI scanner 110, the terminal 130, and/or the storage device 150. For example, the processing device 140 obtains the preliminary scanning data and the navigation data of an imaging region of an imaging target; determines temporal information relating to at least one temporal dimension of the imaging region based on the navigation data; determines spatial information related to at least one spatial dimension of the imaging region based on the preliminary scanning data and the temporal information; and generates a reconstructed image by performing, based on the temporal information and the spatial information, motion correction during an image reconstruction process of the preliminary scanning data. In some embodiments, the processing device 140 is a single server or a server group. The server group is centralized or distributed. In some embodiments, the processing device 140 is local or remote.

The storage device 150 stores data and/or instructions. In some embodiments, the storage device 150 stores the data obtained from the MRI scanner 110, the terminal 130, and/or the processing device 140. For example, the storage device 150 stores real-time MRI images. In some embodiments, the storage device 150 stores the data and/or instructions that the processing device 140 performs or uses to perform the exemplary methods described in the present disclosure. In some embodiments, the storage device 150 is connected to the network 120 to communicate with one or more components of the application scenario 100 of the system for MRI (e.g., the MRI scanner 110, the processing device 140, the terminal 130, etc.). The one or more components of the application scenario 100 of the system for MRI accesses the data or the instructions stored in the storage device 150 through the network 120. In some embodiments, the storage device 150 is directly connected to or in communication with the one or more components of the application scenario 100 of the system for MRI (e.g., the MRI scanner 110, the processing device 140, the terminal 130, etc.). In some embodiments, the storage device 150 is a portion of the processing device 140.

It should be noted that the application scenarios 100 is provided for illustrative purposes only and is not intended to limit the scope of the present disclosure. For those skilled in the art, a variety of modifications or variations may be made in accordance with the description of the present disclosure. For example, the application scenario 100 also includes an input device and/or an output device. For another example, the application scenario 100 implements similar or different functionality on other devices. However, these changes and modifications do not depart from the scope of the present disclosure.

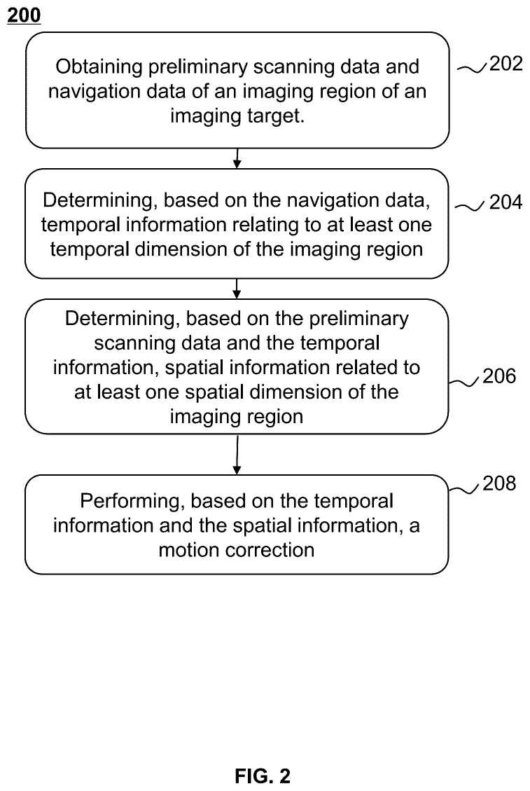

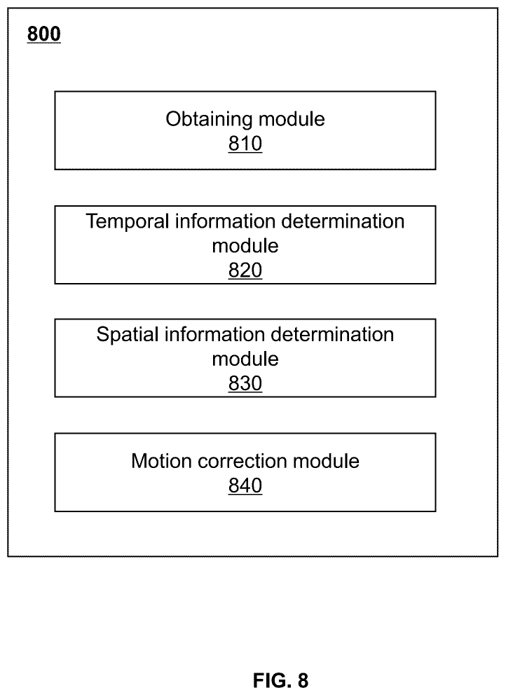

FIG. 2 is a flowchart illustrating an exemplary method for MRI according to some embodiments of the present disclosure. In some embodiments, a process 200 is performed by a system for MRI (e.g., a system 800 for MRI illustrated in FIG. 8) or a processor (e.g., the processing device 140). As shown in FIG. 2, the process 200 includes the following operations.

In operation 202, the processing device may obtain preliminary scanning data and navigation data of an imaging region of an imaging target.

In some embodiments, by applying an MRI pulse sequence to the object (the imaging target), MRI signals (e.g., one or more echoes) are generated. By filling the MRI signals received by a receiving coil along a preset sampling trajectory into K-space, K-space data is obtained. For example, in an MRI scenario of imaging abdomen, the preliminary scanning data is K-space data collected during a free breathing of the patient.

The scanned object (the imaging target) may be biological or non-biological. For example, the scanned object includes a patient, a man-made object, etc. For another example, the scanned object includes a specific portion, organ, tissue, and/or physical point of the patient. Merely by way of example, the scanned object includes a head, a brain, a neck, a body, shoulders, arms, a chest, a heart, a stomach, a blood vessel, a soft tissue, knees, feet, etc., or a combination thereof. The imaging region may be a region of interest (ROI) of the scanned object, and may be at least a portion of a region of the scanned object. The imaging region may be at least one layer or volume of the scanned object.

In some embodiments, the pulse sequence includes a spin echo (SE) sequence, a gradient echo sequence, a diffusion sequence, an inversion recovery (IR) sequence, etc., or any combination thereof. For example, the SE sequence includes a fast spin echo (FSE) pulse sequence, a turbo spin echo (TSE) pulse sequence, a fast acquisition with relaxation-enhanced (rare) pulse sequences, a half-Fourier capture of single-shot turbo spin echo (HASTE) pulse sequence, a turbo gradient spin echo (TGSE) pulse sequence, etc., or any combination thereof. For another example, the gradient echo sequence includes a balanced steady state free precession (bSSFP) pulse sequence, a spoiled gradient echo (GRE) pulse sequence, an echo planar imaging (EPI) pulse sequence, a steady state free precession (SSFP), etc., or any combination thereof.

In some embodiments, the preliminary scanning data includes high spatial resolution image data related to at least one spatial dimension of the scanned object (e.g., a slice selection direction, a phase encoding direction, a frequency encoding direction (readout direction), etc.). Exemplary spatial dimensions include the slice selection direction, the phase encoding direction, the frequency encoding direction, etc., or any combination thereof. In some embodiments, the preliminary scanning data is obtained by sampling different K-space lines (sampling trajectories) in the K-space via a pseudo-randomized sampling manner. The slice selection direction corresponds to a Kz direction in the K-space and a Z direction defined by the coordinate system in FIG. 1; the phase encoding direction corresponds to a Ky direction in the K-space and a Y direction defined by the coordinate system in FIG. 1; and the readout direction corresponds to a Kx direction in the K-space and an X direction defined by the coordinate system in FIG. 1.

In some embodiments, the navigation data includes high temporal resolution data related to at least one temporal dimension of an object (e.g., the respiration motion, a T1 relaxation, etc.). The at least one temporal dimension includes any dimension that reflects a feature or dynamic information of the scanned object over time. In some embodiments, the at least one temporal dimension of the scanned object includes a dimension associated with an elapsed time. In some embodiments, the at least one temporal dimension of the scanned object includes one or more dimensions related to other information, such as a heart motion, a respiration motion, a T1 relaxation, a T2 relaxation, a chemical exchange saturation transfer (CEST), a contrast agent dynamic, a T1p contrast, a molecular diffusion, etc.

In some embodiments, the preliminary scanning data is obtained by performing an undersampling, a full sampling or an oversampling on different K-space lines (the sampling trajectories) in the K-space.

In some embodiments, the sampling trajectories include a Cartesian sampling trajectory and a non-Cartesian sampling trajectory. An exemplary non-Cartesian sampling trajectory includes a spiral trajectory, a radial trajectory, an oscillating trajectory, etc., or any combination thereof. In some embodiments, one sampling trajectory corresponds to one or more echoes, for example, one or more echoes are filled into the K-space along one sampling trajectory. Merely by way of example, one echo is filled into the K-space along one sampling trajectory.

In some embodiments, the preliminary scanning data is obtained by sampling based on a GRASP sampling method. A core principle of a GRASP technology is to achieve a high acceleration while maintaining an image quality through a special sampling manner (a golden angle radial sampling) and a compression sensing (CS) algorithm. For example, when sampling, an angle of each sampling point is first determined to ensure that an angular interval of each sample is a golden angle) (137.5° to ensure a uniform distribution of the sampling points in the K-space. After that, data is collected along different radial directions to gradually fill the K-space. Due to a radial sampling, a frequency-domain (the K-space) sampling mode of the image is different from a traditional rectangular grid mode, which better handles motion artifacts.

The preliminary scanning data may correspond to at least two radial lines in the K-space with different readout angles. In some embodiments, the processing device 140 obtains the preliminary scanning data by sampling the at least two radial lines in the K-space according to the golden angle radial sampling mechanism. By adopting the golden angle radial sampling mechanism, a plurality of radial lines uniformly distributed in and covering the K-space may be obtained in a relatively short period of time, which improves a scanning efficiency, and reduces an amount of calculation and a calculation time. It should be understood that the preliminary scanning data may be sampled using any other readout angle (e.g., a randomly set readout angle) as practically necessary (e.g., based on requirements regarding the scanning time and/or the imaging quality).

In some embodiments, the navigation data is K-space data and corresponds to a subset of the K-space (e.g., one or more K-space lines included in the K-space), which is obtained by repeatedly sampling the subset of the K-space at a high sampling frequency. For example, the navigation data corresponds to a K-space line in the K-space that passes through a center of the K-space (e.g., a position where Kx=Ky=0 in a two-dimensional (2D) K-space, or a position where Kx=Ky=Kz=0 in a 3D K-space), which is obtained by repeatedly sampling the K-space line (data line) using the high sampling frequency. The high sampling frequency refers to a sampling frequency above a threshold frequency. The threshold frequency may be a default value, or may be manually determined by the user, or may be determined by the processing device 140 based on data analysis. For example, the threshold frequency is determined based on at least one temporal dimension to be analyzed. Merely by way of example, the temporal dimension is correlated with the respiration motion of the scanned subject and the scanned subject has a respiration period close to 0.75 seconds. In order to collect the dynamic information related to the respiration motion of the scanned object, the sampling frequency requires a threshold frequency greater than 1/0.75 hertz (Hz). For another example, the threshold frequency is determined based on practical requirements (e.g., an accuracy requirement), experience, a data modeling, etc.

In some embodiments, the processing device further obtains the navigation data by: determining a collection period for collecting the navigation data; and, collecting the navigation data from magnetic resonance signals based on the collection period. Or, the processing device extracts the navigation data from at least a portion of the preliminary scanning data to obtain the navigation data. That is, the navigation data is obtained by extracting from at least a portion of the preliminary scanning data instead of performing sampling, so that an imaging time is reduced, and an imaging efficiency is improved.

The collection period refers to a time period when collecting the navigation data, or when collecting the navigation data according to a certain time interval. Just as an example, the radial lines (data lines) at constant angles in the K-space are repeatedly sampled at fixed time intervals (the collection period) to obtain navigation signals. The collection period may be set according to the requirement, and this embodiment does not limit the specific determination of the acquisition period.

In some embodiments, the navigation data is obtained by the radial sampling. The navigation data may correspond to the radial line with a constant angle (e.g., 0°, 10°, 20°, 30°, 100°, 180°, etc.) in the K-space of the preliminary scanning data.

By collecting the preliminary scanning data and the navigation data respectively, a signal interference between the preliminary scanning data and the navigation data may be avoided, so as to reflect a state of the imaging region and the navigation information more realistically, and improve the accuracy of the data.

The navigation data and the preliminary scanning data may be obtained in any sampling order during the MRI scan of the scanned subject. In some embodiments, the navigation data and the preliminary scanning data are obtained interleaved during the MRI scan of the subject. For example, a first count of K-space lines for obtaining the preliminary scanning data is sampled after or before every readout of a second count of K-space lines for obtaining the navigation data. The first count and the second count may be any positive integer, such as 1, 2, 3, 5, 10, etc.

In some embodiments, the first count and the second count are set according to actual requirements, for example, a sampling frequency of the navigation data needs to be greater than the threshold frequency and/or enough preliminary scanning data need to be obtained for image reconstruction. In some embodiments, the ratio of the first count to the second count relates to the type of the subject to be imaged. For example, to image the heart of a patient, the ratio of the first count to the second count is equal to 1:1. For another example, to image an organ other than the heart (e.g., an arm, a knee), the ratio of the first count to the second count is equal to 10:1.

Taking GRASP sampling schedule as an example, the preliminary scanning data is obtained along a plurality of radial lines in K-space of different readout angles. In some embodiments, the processing device 140 obtains the preliminary scanning data by sampling a plurality of radial lines in K-space with readout angles of 0*θ, 1*θ, 2*θ, 3*θ, 4*θ, . . . , and N*θ, wherein N denotes a positive integer greater than 1 and e denotes the golden angle. The navigation data may be obtained by sampling a radial line in the K-space of the constant angle (e.g., 0°) repeatedly at a regular interval. For example, the navigation data is obtained by sampling the 0° radial spoke repeatedly every odd readout, e.g., the first readout by sampling 0° radial spoke for the navigation data, the second readout by sampling 0° radial spoke for the preliminary scanning data, the third readout by sampling 0° radial spoke for the navigation data, the fourth readout by sampling 1*θ radial spoke for the preliminary scanning data, the fifth readout by sampling 0° radial spoke for the navigation data, the sixth readout by sampling 2*θ radial spoke for the preliminary scanning data, etc.

In operation 204, the processing device may determine, based on the navigation data, temporal information relating to at least one temporal dimension of the imaging region.

The temporal information may include imaging feature information associated with at least one temporal dimension at different time points. In some embodiments, the temporal information is represented as a temporal basis function. Each temporal basis function is related to the temporal dimension of the scanned object. For example, the temporal information includes one or more heart temporal basis functions related to the heart motion of the scanned object, one or more respiration temporal basis functions related to the respiration motion of the scanned object, one or more temporal basis functions related to a T1 recovery temporal basis function related to T1 relaxation of the scanned subject, etc., or any combination thereof. The temporal basis functions related to the temporal dimension reflects the dynamic information along the temporal dimension (a time-varying dimension) and includes high temporal resolution information.

In some embodiments, the processing device organizes the navigation data into a matrix to obtain a K-space matrix. Each column of the K-space matrix represents a sampling at a time point, and each row represents a spatial position or a channel. Further, based on the K-space matrix, the temporal information is determined. For example, the processing device determines the temporal information associated with at least one temporal dimension of the imaging region based on the K-space matrix by a singular value decomposition (SVD) algorithm.

Merely by way of example, the K-space matrix is denoted as K1. The K-space matrix K1 is expressed as

$$( \begin{matrix}κ ( {k}_{1} , {t}_{1} ) & ⋯ & κ ( {k}_{1} , {t}_{N} ) \\ κ ( {k}_{2} , {t}_{1} ) & ⋯ & κ ( {k}_{2} , {t}_{N} ) \\ ⋮ & ⋯ & ⋮ \\ κ ( {k}_{c} , {t}_{1} ) & ⋯ & κ ( {k}_{c} , {t}_{N} )\end{matrix} ) ,$$

where, an element in the K-space matrix K1 denotes the K-space data obtained by a particular coil channel at a particular moment. For example, κ(k_{c}, t₁) denotes K-space data (navigation data) collected by a coil channel k_{c} at a moment t₁. The processing device 140 may determine a conversion factor T and temporal information φ by performing the SVD on the K-space matrix K1 according to Formular (1):

K₁=UₖDφ, (1)

where, Uₖ denotes a projection factor matrix, φ denotes the temporal information (e.g., the temporal information expressed by at least one temporal information matrix), and D denotes a singular value matrix. The conversion factor T is determined based on the projection factor matrix Uₖ and the singular value matrix D. For example, the conversion factor T may be (UₖD) or

$$( {D}^{- 1} {U}_{k}^{H} ) ,$$

where,

$${U}_{k}^{H}$$

denotes a conjugate transpose matrix of the projection factor matrix Uₖ, and D⁻¹ denotes an inverse matrix of the singular value matrix D.

In operation 206, the processing device may determine, based on the preliminary scanning data and the temporal information, spatial information related to at least one spatial dimension of the imaging region.

The spatial information may include high spatial resolution information along a spatial variation dimension. For example, the spatial information reflects a relationship between pixel information of the scanned object in the image domain and spatial information of the scanned object in the physical domain. In some embodiments, the spatial information is represented as a base image that includes high spatial resolution information. Different spatial information is represented as a base image including different high spatial resolution information.

In some embodiments, the processing device constructs an optimization function related to spatial information. The optimization function combines the preliminary scanning data and the temporal information φ. The processing device determines at least one spatial information by solving the optimization function. For example, the processing device determined the spatial information u of the scanned object based on the first optimization function shown in Formular (2):

$$\hat{u} = {arg min}_{u} {‖ {d}_{img} - Ω FSu φ ‖}_{2}^{2} \qquad ( 2 )$$

where û denotes the optimal spatial information determined by solving Formular (2), u denotes the spatial information variable of the scanned object, which is also referred to as preliminary spatial information (e.g., the spatial information represented by at least one spatial information matrix), Ω denotes a downsampling operator (which is omitted in some cases), F denotes a Fourier transform operator, S denotes a coil sensitivity operator, and d_{img} denotes the preliminary scanning data.

For another example, the processing device 140 determines the spatial information u of the scanned object based on a second optimization function shown in Formular (3):

$$\hat{u} = {arg min}_{u} {‖ {d}_{img} - Ω FSu φ ‖}_{2}^{2} + R ( u ) \qquad ( 3 )$$

where R(u) denotes a regularization factor (also referred to as a first constraint factor in the present disclosure).

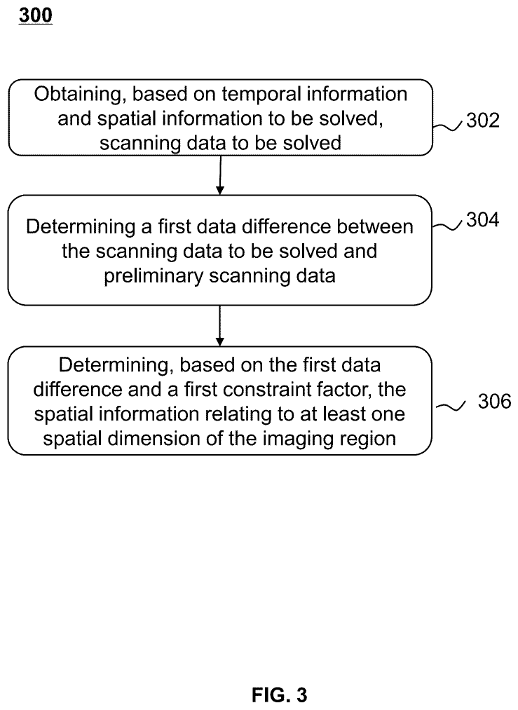

More detailed descriptions of obtaining the spatial information may be seen in the related descriptions in FIG. 3.

In operation 208, the processing device may perform, based on the temporal information and the spatial information, a motion correction.

The motion correction refers to a process of using techniques and algorithms to compensate for an image distortion or artifacts due to motions of the scanned object.

In some embodiments, the processing device generates a reconstructed image in various manners, such as through machine learning models, image reconstruction algorithms, etc. For example, an image reconstruction model is pre-trained by machine learning techniques. The preliminary scanning data, the temporal information, and the spatial information are input to the image reconstruction model, and the image reconstruction model, when processing the input data, performs the motion correction based on the temporal information and the spatial information, and generates and outputs the reconstructed image based on a motion correction result and the preliminary scanning data.

In some embodiments, the processing device divides the preliminary scanning data and determines a deformation field corresponding to the divided data based on the temporal information and the spatial information; and generates a reconstructed image based on the preliminary scanning data and the deformation field.

In some embodiments, the deformation field is generated based on the temporal information and the spatial information. For example, the processing device first generates preliminary images based on the temporal and spatial information, and then determines the deformation field based on the preliminary images and an image of the object in a standard motion stage. For exemplary purposes, an exemplary manner for generating the preliminary images is described below.

For example, the processing device generates preliminary images of the scanned object by determining a product of the at least one temporal information matrix and the at least one spatial information matrix. The at least one temporal information matrix includes the temporal information and the at least one spatial matrix factor includes the spatial information. Merely by way of example, the processing device generates the preliminary images of the scanned object according to Formular (4):

A=u₀φ (4)

where, A denotes the preliminary images, φ denotes the temporal information in a form of the at least one temporal information matrix, and u₀ denotes the spatial information in a form of the at least one spatial factor matrix.

It should be noted that there is more than one deformation field, and the more than one deformation field correspond to different motion stages of the object, respectively.

In some embodiments, the processing device generates the reconstructed image of the scanned object corresponding to a particular time-varying dimension based on the temporal information matrix and the spatial information matrix corresponding to the particular time-varying dimension. For example, the processing device generates a reconstructed image of a heart by determining the product of the spatial information matrix and the temporal information matrix that includes information related to a respiration motion. The temporal information matrix related to a heart motion includes the temporal information related to the respiration motion.

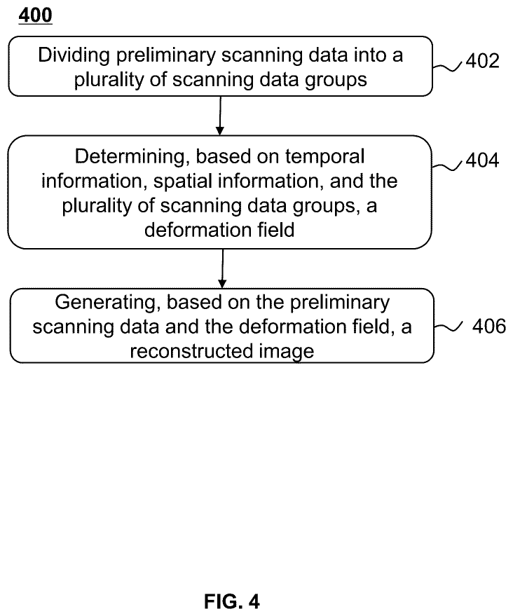

In some embodiments, the reconstructed image is also generated based on a preliminary imaging time, the temporal information, and the spatial information in other ways as well, which are not limited by this embodiment. Further description of generating the reconstructed image may be found in the related descriptions of FIG. 4.

In some embodiments of the present disclosure, the temporal information and the spatial information are determined by collecting the preliminary scanning data and the navigation data of the scanned object. The deformation field for performing the motion correction is obtained based on the temporal information and the spatial information. The reconstructed image with a high quality is generated based on the deformation field and the preliminary scanning data. During the determination of the deformation field, accurate and detailed motion information (e.g., the respiration information) is obtained. By introducing the deformation field or directly performing the motion correction on the scanning data, an interference caused by a physiological motion of the object is resolved, and a quality of the reconstructed image is improved.

In some embodiments, the processing device establishes a first optimization model based on the temporal information, spatial information to be solved, and the preliminary scanning data; and determines the spatial information relating to at least one spatial dimension of the imaging region by minimizing a value of the first optimization model. For example, the first optimization model established is shown in above Formular (3). By solving the first optimization model, and minimizing a value of the first optimization model, the spatial information is determined. A process for establishing the first optimization model can be found in FIG. 3.

FIG. 3 is a flowchart illustrating an exemplary process for obtaining spatial information according to some embodiments of the present disclosure. In some embodiments, a process 300 is performed by a system for MRI (e.g., the system 800 for MRI illustrated in FIG. 8) or a processor (e.g., the processing device 140). As shown in FIG. 3, the process 300 includes the following operations.

In operation 302, the processing device may obtain, based on temporal information and spatial information to be solved, scanning data to be solved.

The spatial information to be solved refers to a spatial information variable added during a process of obtaining the spatial information. As described in Formular (2), the spatial information to be solved corresponds to u, which is also referred to as preliminary spatial information.

In some embodiments, as an independent variable for solving formula (2), the spatial information to be solved is any spatial information matrix that satisfies an operation rule of Formular (2) (e.g., dimensions and values of elements in the matrix are arbitrary values).

The scanning data to be solved refers to data determined based on the temporal information and the spatial information to be solved. In some embodiments, the scanning data to be solved is determined based on the temporal information, the spatial information to be solved, and a preset operator.

For example, referring to Formular (2) or (3) of operation 206 above, the scanning data to be solved is a product of the temporal information, the spatial information to be solved, a downsampling operator, a Fourier transform operator, and a coil sensitivity operator. The preset operator is set in advance, and this embodiment does not limit a specific type of the operator.

In operation 304, the processing device may determine a first data difference between the scanning data to be solved and preliminary scanning data.

The data difference is used to measure an amplification effect of certain frequency components in the scanning data to be solved and the preliminary scanning data. For example, by controlling a magnitude of the data difference, an over-amplification of certain frequency components during an MRI reconstruction is avoided, thereby improving image quality and accuracy.

In some embodiments, the data difference is expressed by a square of a norm, e.g.,

$${‖ * ‖}_{2}^{2}$$

in the above Formular (2) and Formular (3) is the square of a norm.

In some embodiments, the first data difference is the square of the norm of a difference between the scanning data to be solved and the preliminary scanning data.

In operation 306, the processing device may determine, based on the first data difference and a first constraint factor, the spatial information relating to at least one spatial dimension of the imaging region.

The constraint factor refers to a constraint added during a solution calculation. In some embodiments, the constraint factor is an added regularization factor.

The first constraint factor is the regularization factor constructed based on the spatial information to be solved.

In some embodiments, the processing device constructs an optimization function based on the first data difference and the first constraint factor, and determines the spatial information by solving the optimization function. For example, the constructed optimization function is the second optimization function as shown in Formular (3).

In this embodiment, by solving a spatial basis for obtaining the scanning data to be solved with a high-image-quality and a high temporal resolution, a final reconstructed image obtained subsequently is made more accurate, artifacts and noises in the final reconstructed image are reduced, and clarity and contrast of the image are improved.

FIG. 4 is a flowchart illustrating an exemplary process for generating a reconstructed image according to some embodiments of the present disclosure. As shown in FIG. 4, a process 400 includes the following operations. In some embodiments, the process 400 is performed by a system for MRI (e.g., the system 800 for MRI illustrated in FIG. 8) or a processor (e.g., the processing device 140).

In operation 402, the processing device may divide preliminary scanning data into a plurality of scanning data groups.

The “dividing” refers to dividing the preliminary scanning data into different groups (bins) in a certain way. The preliminary scanning data in each group (bin) after division has same or similar attributes.

In some embodiments, the processing device divides the preliminary scanning data based on a motion stage of the scanned object or according to a temporal direction of the data.

For example, the preliminary scanning data may be divided based on a respiration stage of the scanned object, based on a heartbeat period of the scanned object, or based on the temporal direction. Taking the division based on the respiration stage as an example, the processing device divides a complete respiration period into a plurality of respiration stages (e.g., a preliminary inhalation stage, a mid-inspiratory stage, an end-inspiratory stage, a preliminary exhalation stage, a mid-inspiratory stage, an end-inspiratory stage, etc.). For example, for the preliminary scanning data collected when the scanned object breathes freely, the preliminary scanning data includes data from a plurality of time points, and the preliminary scanning data is divided into different bins based on the respiration state of the preliminary scanning data corresponding to each time point. The respiration state corresponding to one time point reflects a fluctuation of a abdomen or a chest, a breathing volume, etc. For example, the complete respiration period is divided into a plurality of respiration stages (e.g., the preliminary inhalation stage, the mid-inspiratory stage, the end-inspiratory stage, the preliminary exhalation stage, the mid-inspiratory stage, the end-inspiratory stage, etc.), and each respiration stage corresponds to a fluctuation range of the abdominal or the chest or a respiration volume range. The preliminary scanning data is divided according to the respiration state corresponding to each time point. At this time, the preliminary scanning data in each bin corresponds to the same respiration stage, that is, each group of preliminary scanning data corresponds to a motion stage of a physiological motion of an imaging target, and has the same or similar attributes.

In some embodiments, the respiration state corresponding to each time point is determined during the data collection. For example, a respiration acquisition device (e.g., a respiration belt or a pressure sensor, etc.) is used to monitor a respiration mode of the scanned object, and record the respiration state corresponding to each time point.

In some embodiments, the processing device divides the preliminary scanning data into M groups (bins) based on the M different respiration stages of the scanned object. A value of M may be determined based on a respiration smoothness of a patient. The respiration smoothness is used to reflect a degree of respiration calmness of the scanned object. The processing device determines a respiration rate of the scanned object at each time point, and the respiration rate is measured in terms of an amount of expiration/inspiration per unit of time, or, in terms of a change in the fluctuation of the chest or the abdomen. The respiration rate may be obtained by monitoring a motion (such as the fluctuation) of the chest or the abdomen of the object, or an amount of breathing, with a respiration acquisition device (such as a respiration belt or a pressure sensor, etc.), and forming a respiration curve. A change degree of the respiration curve is used to determine whether the breathing is smooth or rapid, and then the respiration rate of the subject at each time point is determined based on the curve. After that, a variance of the determined plurality of respiration rates is determined, and an inverse of the variance is taken as the respiration smoothness; the value of M is determined based on the respiration smoothness of the patient. Specifically, the smaller the respiration smoothness, the greater the value of M. The processing device may determine the value of M based on a pre-established linear relationship between the respiration smoothness and the value of M.

In some embodiments, the purpose of binning is to group similar data in the preliminary scanning data together based on the difference of the respiration motions of the scanned object in different time periods so that the similar data are processed together. The patient with low respiration smoothness are considered to have unstable respiration, who has a great difference in respiration at different stages (e.g., the expiration and the inspiration). To ensure that the respiration within each respiration stage is more consistent, finer respiration stages are needed, which means that a greater value of M needs to be used; whereas, the patient with high respiration smoothness is considered to have more stable respiration, who has a smoother respiration at adjacent time points, and a smaller value of M is used to ensure that the respiration within each respiration stage is more consistent.

For another example, the processing device also performs the division based on the temporal direction. When the preliminary scanning data is collected under consecutive time points (which form a time period), the aforementioned time period is divided into a plurality of small time intervals, and then the preliminary scanning data is divided into different bins based on the time intervals and the acquisition time points of the preliminary scanning object. At this time, the data in each bin is in the same time interval, and also has the same or similar attributes.

In some embodiments, the processing device also performs the division based on both the motion stage and the temporal direction as described above. By performing the division based on both the motion stage and the temporal direction, the division is performed using a two-dimensional (2D) grid, where the data in each grid has the same motion stage and is in the same time interval.

In operation 404, the processing device may determine, based on temporal information, spatial information, and the plurality of scanning data groups, a deformation field of the preliminary scanning data.

The deformation field is expressed by a mathematical model that describes a displacement vector of each voxel (or pixel) in the image over time. The displacement vector reflects a position change of each voxel (or pixel) from a reference state (e.g., a first frame of an image in a time series) to another state (e.g., another frame of the image in the time series). In this embodiment, the deformation field is used to describe a transformation relationship from one motion stage of the scanned object to another motion stage of the scanned object, e.g., the deformation field is used to indicate the transformation relationship between the motion stages (the respiration stages) corresponding to different groups of the divided preliminary scanning data.

In some embodiments, the processing device determines the deformation field in various manners based on the temporal information, the spatial information, and the plurality of scanning data groups. For example, the deformation field is determined by a trained machine learning model, or determined by an algorithm based on an image registration. This embodiment does not limit specific manners of determining the deformation field.

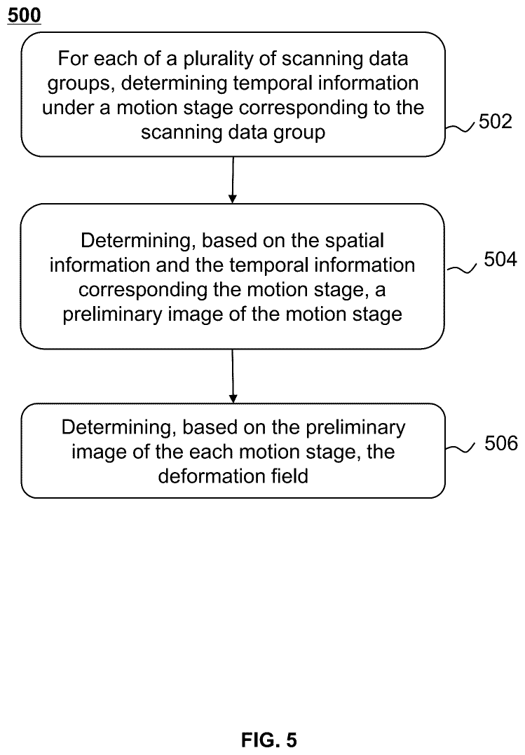

In some embodiments, the processing device establishes a second optimization model based on the deformation field, a reconstruction image to be solved, and the preliminary scanning data; and determines the reconstruction image by minimizing a value of the second optimization model. The established second optimization model is shown in Formular (5). Exemplarily, a process for establishing and solving the second optimization model to determine the reconstruction image can be found in FIG. 5.

Further instructions on determining the deformation field may be found in the descriptions of FIG. 5.

In operation 406, the processing device may generate, based on the preliminary scanning data and the deformation field, the reconstructed image.

In some embodiments, the processing device determines the reconstructed image in various manners based on the preliminary scanning data and the deformation field. For example, the reconstructed image is determined based on machine learning techniques, or the reconstructed image is determined by constructing an optimization function.

Exemplarily, the processing device constructs a third optimization function and determines the reconstructed image based on the preliminary scanning data and the deformation field by solving the third optimization function. Specifically, the processing device obtains correction scanning data to be solved based on the deformation field and a reconstructed image to be corrected; determines a second data difference between the correction scanning data to be solved and the preliminary scanning data; and, determines the reconstructed image based on the second data difference and a second constraint factor. The third optimization function is constructed based on the second data difference and the second constraint factor, and by solving the third optimization function, the reconstructed image is determined.

In some embodiments, the third optimization function constructed is shown in Formular (5):

$$\hat{X} = {arg min}_{X} {\sum }_{i} ‖ {d}_{i , img} - {Ω}_{i} {FSM}_{i} X {‖}_{2}^{2} + λ Q ( X ) \qquad ( 5 )$$

where, X denotes the reconstructed image to be solved and is a reconstructed image variable of the third optimization function; \hat{X} denotes the reconstructed image obtained by solving the third optimization function when an optimization target of the third optimization function is made optimal; d_{i,img} denotes the preliminary scanning data of the ith motion stage (e.g., respiration stage); Mᵢ denotes the deformation field from the ith motion stage to a standard motion stage; Ωᵢ denotes a downsampling operator of the ith motion stage; F denotes a Fourier transform operator; S denotes a coil sensitivity operator;

$${‖ * ‖}_{2}^{2}$$

denotes a square of a norm; Q(X) denotes the second constraint factor; λ denotes a coefficient of the second constraint factor.

A description of the standard motion stage may be found in the related descriptions of FIG. 5.

In some embodiments, the second constraint factor is a regularization factor along the temporal direction, which is obtained by constructing a regularization term along the temporal direction. The square of the norm

$${‖ * ‖}_{2}^{2}$$

is the second data difference described above.

More descriptions of constructing the third optimization function to solve the reconstructed image may be found in descriptions of Formulars (2) and (3) above.

In some embodiments, the processing device obtains the reconstructed image via a third neural network based on the preliminary scanning data and the deformation field. For example, the processing device inputs the preliminary scanning data and the deformation field into the third neural network, and the third neural network outputs the reconstructed image.

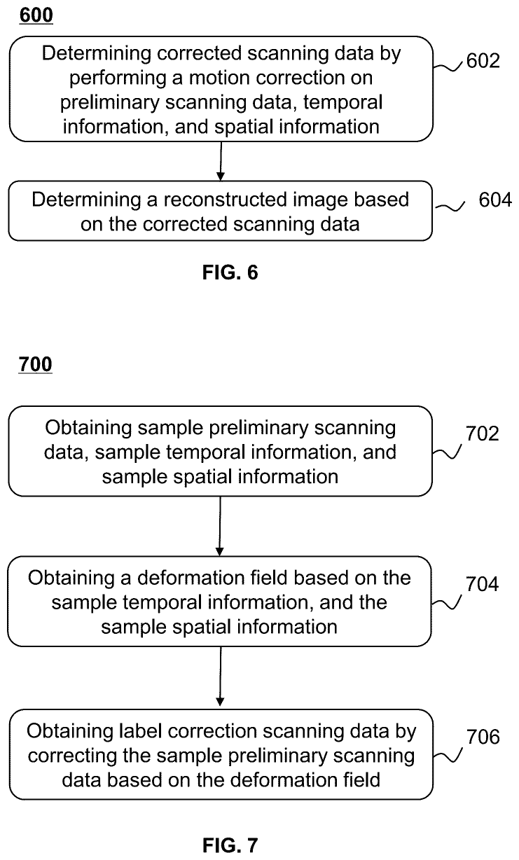

The third neural network may be obtained by training. For example, the training data is constructed by using historical preliminary scanning data and a historical deformation field as training samples (input), and using a historical reconstructed image as a label. The training data is used for training a preliminary neural network to obtain the third neural network. The training data may be obtained in various manners. For example, a sample object is scanned when the sample object is in a free breathing state to obtain the historical preliminary scanning data. When the sample object is a breath-holding state, the sample object is scanned to obtain historical scanning data, and image reconstruction is performed on the historical scanning data to obtain the historical reconstructed image. As another example, a sample object is scanned when the sample object is in a free breathing state to obtain the historical preliminary scanning data. The historical reconstructed image is obtained based on the historical preliminary scanning data in a manner shown in FIG. 6.

In this embodiment, by using the temporal information and the spatial information to determine the deformation field, and by using the deformation field to perform the motion correction to generate the reconstructed image, an impact of the motion on an image quality is reduced. In addition, in this embodiment, instead of directly generating the final reconstructed image through a low-rank acceleration method using the temporal information and the spatial information, the deformation field is determined using the temporal information and the spatial information, and then the deformation field is applied to the optimization function based on the temporal regularization or the third neural network to generate the final reconstructed image. In this way, an image quality problem brought by simply using the low-rank acceleration method is avoided, and required computing resources and memory are reduced.

FIG. 5 is a flowchart illustrating an exemplary process for determining a deformation field according to some embodiments of the present disclosure. As shown in FIG. 5, a process 500 includes the following operations. In some embodiments, the process 500 is performed by a system for MRI (e.g., the system 800 for MRI illustrated in FIG. 8) or a processor (e.g., the processing device 140). The deformation field of the preliminary scanning data includes a motion deformation field of each of a plurality of scanning data groups.

In operation 502, for each of a plurality of scanning data groups, the processing device may determine temporal information under a motion stage corresponding to the scanning data group.

As each scanning data group is divided from the preliminary scanning data, a manner of determining the temporal information in the motion stage corresponding to each scanning data group may be similar to the manner of determining the temporal information based on the preliminary scanning data. For example, assuming that a total of 10,000 time points are extracted based on navigation data, the temporal information in operation 204 includes values for each of these 10,000 time points; and for each scanning data group, the corresponding temporal information includes the value of the time point of the corresponding scanning data. For example, assuming that the 10,000 time points are divided into 3 respiration stages, that is, 3 scanning data groups, the first respiration stage includes time point 1 to time point 2000, then for the first scanning data group, its temporal information is an average value of the value corresponding to time point 1, the value corresponding to time point 2, . . . and the value corresponding to time point 2000.

More specifically, taking the respiration motion as an example, the respiration is divided into respiration stage 1, respiration stage 2, respiration stage 3, assuming that the preliminary scanning data collected includes 1000 time points (denoted as time points t1~t1000), the preliminary scanning data is divided, with t1~t300 divided into boxes corresponding to respiration stage 1, t301~t500 divided into boxes corresponding to respiration stage 2, t501~t1000 divided into boxes corresponding to respiration stage 3; then for each respiration stage:
Temporal information for respiration stage 1=the average value of “Temporal information for moment t1, temporal information for moment t2, . . . , and time for moment t300 information”;
Temporal information for respiration stage 2=the average value of “Temporal information of moment t301, temporal information of moment t302, . . . , moment temporal information of moment t500”;
Temporal information of respiration stage 3=the average value of “temporal information of moment t501, temporal information of moment t502, . . . , temporal information of moment t1000”.

More descriptions on determining the temporal information may be found in the descriptions of operation 204.

In some embodiments, the processing device may divide the navigation data into the plurality of scanning data groups based on the acquisition time points of the navigation data. For each scanning data group, the processing device may determine the temporal information based on the navigation data corresponding to the scanning data group using the method illustrated in operation 204.

In operation 504, the processing device may determine, based on the spatial information and the temporal information corresponding the motion stage, a preliminary image of the motion stage.

In some embodiments, the processing device performs calculations based on the spatial information and the temporal information for each of the motion stages, for example, multiplying the spatial information and the temporal information for each of the motion stages to determine the preliminary image for each of the motion stages.

Exemplarily, the preliminary image is determined by the following formula (6):

Aᵢ=u₀φᵢ (6)

where, Aᵢ denotes the preliminary image of the i th motion stage, u₀ denotes the spatial information, and φᵢ denotes the temporal information corresponding to the ith motion stage.

It should be noted that a difference between Formular (6) and Formular (4) is that Formular (4) may be regarded as a plurality of preliminary images that are solved, while Formular (6) is a single preliminary image that is solved for each scanning data group, that is, A in Formular (4) is a set of preliminary images Aᵢ corresponding to different motion stages.

In operation 506, the processing device may determine, based on the preliminary image of the motion stage, the motion deformation field of the scanning data group.

In some embodiments, the processing device determines the motion deformation field based on the preliminary image of the each motion stage and an image of a standard motion stage. The standard motion stage may be a motion stage corresponding to a certain motion stage in a physical motion of the scanned object. Taking the respiration motion as an example, a standard respiration stage is a certain respiration stage arbitrarily selected from a plurality of respiration stages, or is a certain respiration stage determined in a certain manner.

Exemplarily, the processing device determines a respiration consistency for each respiration stage of the scanned object and determines the respiration stage with the highest respiration consistency as the standard respiration stage. The respiration consistency reflects a consistency of breathing. Following the example above, assuming that a respiration is divided into 3 respiration stages, according to a recognition manner of the respiration stages, time points t1-t100 in the preliminary scanning data are recognized as respiration stage 1, time points t101-t300 are recognized as respiration stage 2, and time points t301-t500 are recognized as respiration stage 3.

Respiration consistency for respiration stage 1=1/(a variance of respiration rate at time point t1, respiration rate at time point t2, . . . , respiration rate at time point t100)

Respiration consistency for respiration stage 2=1/(a variance of respiration rate at time point t101, respiration rate at time point t102, . . . , respiration rate at time point t300)

Respiration consistency for respiration stage 3=1/(a variance of respiration rate at time point t301, respiration rate at time point t302, . . . , respiration rate at time point t500)

As the standard respiration stage is used as a benchmark for reference, the standard respiration stage is selected to be one that has a stable respiration and the respiration consistency, which helps to better determine the motion deformation field.

In some embodiments, the processing device determines the motion deformation field based on the preliminary image of each motion stage and the corresponding standard state image through a registration algorithm. The registration algorithm may include a rigid registration algorithm and a non-rigid registration algorithm, such as a mutual information registration algorithm, a free-form registration algorithm, etc., and this embodiment does not limit the specific registration algorithm.

In some embodiments, the processing device also determines the deformation field through a neural network. For example, the processing device inputs the preliminary image of each respiration stage into a first neural network, and the first neural network outputs the deformation field after calculation. The first neural network may, when calculating, arbitrarily select one of the input preliminary images of the plurality of respiration stages as an image of the standard respiration stage, or may additionally input an image of the standard respiration stage for reference, which is not limited by the embodiment. For example, an image in a certain respiration stage is designated as the image of the standard respiration stage. The image of the standard respiration stage may be obtained by performing image reconstruction on the scanning data under the respiration stage.

The first neural network may be obtained by training, e.g., by training the preliminary first neural network using historical preliminary image of each respiration stage as sample data (input), and the deformation field determined by the registration algorithm using the historical preliminary images as a label. The trained first neural network has an ability to determine the deformation field between images corresponding to two motion stages. In the training process, one image is selected as the image of the standard respiration stage from the historical preliminary images, or an additional image is input as the image of the standard respiration stage. For example, a historical preliminary image is designated as the image of the standard respiration stage, or an additional standard motion stage image is included in the sample data for reference. Label data is determined by the registration algorithm, and is the deformation field between the standard breathing stage image and the other images. For example, assuming that there are preliminary images corresponding to 3 motion stages, motion stage 3 is determined as the standard motion stage, and motion deformation field 1 is determined based on the preliminary image corresponding to motion stage 1 and the preliminary image corresponding to motion stage 3, and motion deformation field 1 indicates a transformation relationship between motion stages 1 and 3. Motion deformation field 2 is determined based on the preliminary image corresponding to motion stage 2 and the preliminary image corresponding to motion stage 3, which indicates the transformation relationship between motion stages 2 and 3.

In addition, the above example may be applied to Formular (5) in the embodiment shown in FIG. 4. For example, Mᵢ in Formular (5) includes M₁, M₂ and M₃, which corresponds to the preliminary images of motion stage 1, the motion stage 2 and the motion stage 3. As motion stage 3 is selected as the standard motion stage, when calculating with Formular (5), M₃ is made to be 1.

In the present embodiment, by accurately determining the preliminary image of each motion stage and calculating its deformation field with respect to the standard motion stage, it is possible to accurately correct an image deformation caused by a physiological motion and to improve a stability and the image quality of the reconstructed image finally obtained, and ensure the consistency of the images obtained at different motion stages.

In some embodiments, the processing device establishes a third optimization model based on a reconstruction image to be solved and the corrected scanning data; and determines a reconstructed image by minimizing a value of the third optimization model. The established third optimization model is shown in Formular (7). By solving the third optimization model, the processing device determines the reconstruction image when the value of the third optimization model is minimized.

FIG. 6 is a flowchart illustrating an exemplary process for generating a reconstructed image according to some embodiments of the present disclosure. As shown in FIG. 6, a process 600 includes the following operations. In some embodiments, the process 600 is performed by a system for MRI (e.g., the system 800 for MRI illustrated in FIG. 8) or a processor (e.g., the processing device 140).

In operation 602, the processing device may determine corrected scanning data by performing, based on the temporal information and the spatial information, a motion correction on the preliminary scanning data.

The corrected scanning data refers to scanning data after performing the motion correction on the preliminary scanning data. The temporal information and the spatial information are used to perform the motion correction on the preliminary scanning data.

In some embodiments, the motion correction is performed on the preliminary scanning data by various data correction algorithms to obtain the corrected scanning data.

Exemplarily, the motion correction is performed by a second neural network to obtain the corrected scanning data. Exemplarily, the processing device inputs the preliminary scanning data, the temporal information, and the spatial information into the second neural network to perform the motion correction to determine the corrected scanning data.

The second neural network may be obtained by training a preliminary second neural network with training data.

In some embodiments, the processing device obtains the training data. The training data includes training samples (input) and corresponding labels. The training samples includes sample preliminary scanning data, sample temporal information, and sample spatial information, and the labels includes label corrected scanning data. The preliminary second neural network is trained using the training data to obtain the second neural network.

The training of the second neural network may be carried out by various model training methods, e.g., a gradient descent method, etc., and the specific training methods of the embodiment are not limited.

In some embodiments, the training data for training the second neural network is obtained by: obtaining a first magnetic resonance signal collected from a sample object in a free breathing stage; obtaining, based on the first magnetic resonance signal, the sample preliminary scanning data (filling the first magnetic resonance signal to K space); obtaining the sample temporal information and the sample spatial information based on the sample preliminary scanning data; obtaining a second magnetic resonance signal collected from the sample object in a breath-holding state; and obtaining, based on the second magnetic resonance signal, label correction scanning data (filling the second magnetic resonance signal to K space).

A manner of determining the sample temporal information and the sample spatial information may be found in the manner of determining the temporal information and the spatial information described above, which is not repeated herein.

In this embodiment, the training of the second neural network is achieved by constructing the training data by obtaining the magnetic resonance signals during different respiration periods of the sample object.

In some embodiments, the training data is obtained in other manners to train the second neural network, as described in more detail in FIG. 7.

In operation 604, the processing device may determine the reconstruction image by minimizing a value of the second optimization model.

In some embodiments, the processing device determines the reconstruction image by minimizing a value of the second optimization model in various manners. For example, the reconstructed image is determined using a neural network based on the corrected scanning data, or the reconstructed image is determined based on the corrected scanning data in ways described in the embodiments below.

In some embodiments, the processing device obtains a reconstructed image to be solved; determines, based on the reconstructed image to be solved, scanning data to be solved; determines a third data difference between the scanning data to be solved and the corrected scanning data; and generates, based on the third data difference and a third constraint factor, the reconstructed image.

The above process of determining the reconstructed image may be summarized as determining the reconstruction image by minimizing a value of the second optimization model using a constructed fourth optimization function. In some embodiments, the constructed fourth optimization function is shown in Formular (7):

$$\hat{X} = {arg min}_{X} {‖ \text{?} - Ω FSX ‖}_{2}^{2} + λ Q ( X ) \qquad ( 7 )$$

where, X denotes the reconstructed image to be solved and is a reconstructed image variable of the fourth optimization function; \hat{X} denotes the reconstructed image obtained by solving the fourth optimization function when an optimization object of the fourth optimization function is optimized; [symbol] denotes the corrected scanning data; Ω denotes a downsampling operator; F denotes a Fourier transform operator; S denotes a coil sensitivity operator;

$${‖ * ‖}_{2}^{2}$$

denotes a square of a norm; Q(X) denotes the third constraint factor; λ denotes a coefficient of the third constraint factor.

More instructions for determining the reconstructed image may be found elsewhere in the present disclosure, e.g., the relevant descriptions in FIG. 4. In the present disclosure, by inputting the preliminary scanning data, the temporal information and the spatial information in the second neural network for motion correction to obtain the corrected scanning data, and generating the reconstructed image by reconstructing the correction scanning data, an impact of motion on an image quality is reduced. In addition, in this embodiment, instead of dividing the preliminary scanning data, the motion correction is directly performed on the preliminary scanning data in the K space using the neural network based on the temporal information and the spatial information, so as to reduce the impact of motion.

FIG. 7 is a flowchart illustrating an exemplary process for obtaining training data of a second neural network according to some embodiments of the present disclosure. As shown in FIG. 7, a process 700 includes the following operations. In some embodiments, the process 700 is performed by a system for MRI (e.g., the system 800 for MRI illustrated in FIG. 8) or a processor (e.g., the processing device 140).

In operation 702, the processing device may obtain sample preliminary scanning data, sample temporal information, and sample spatial information.

In operation 704, the processing device may obtain a sample deformation field based on the sample temporal information, and the sample spatial information.

Detailed descriptions on operation 702 and operation 704 may be referred to descriptions in connection with FIGS. 2-5.

In operation 706, the processing device may obtain label correction scanning data by correcting the sample preliminary scanning data based on the sample deformation field.

In some embodiments, the processing device performs an inverse operation based on the sample deformation field. For example, the process shown in FIG. 5 is inversely operated to invert the sample deformation field back to the K space to obtain corresponding scanning data. After that, the inversely inferred scanning data is used to correct sample preliminary scanning data, or to obtain label correction scanning data.

In some embodiments, the processing device may generate a sample reconstructed image based on the sample preliminary scanning data and the sample deformation field using the process 400 in FIG. 4. The processing device may determine the label correction scanning data by performing Fourier transform on the sample reconstructed image.

It is noted that the above descriptions are for explanation and illustration only and are not intended to limit an application scope of the present disclosure. For those skilled in the art, various modifications and changes may be made under the guidance of the present disclosure, and these modifications and changes are within the scope of the present disclosure. For example, storage operations are added between the operations.

FIG. 8 is a modular diagram illustrating an exemplary system for MRI according to some embodiments of the present disclosure. As shown in FIG. 8, a system 800 for MRI includes an obtaining module 810, a temporal information determination module 820, a spatial information determination module 830, and a motion correction module 840. The system 800 for MRI may be implemented on the processing device 140 through software or hardware.

The obtaining module 810 is configured to obtain preliminary scanning data and navigation data.

The temporal information determination module 820 is configured to determine, based on the navigation data, temporal information relating to at least one temporal dimension of the imaging region.

The spatial information determination module 830 is configured to determine, based on the preliminary scanning data and the temporal information, spatial information relating to at least one spatial dimension of the imaging region.

The motion correction module 840 is configured to perform, based on the temporal information and the spatial information, a motion correction.

Detailed descriptions on each module of the system 800 for MRI are referred to in related operations in FIGS. 2-7, which is not repeated here.

It should be noted that the above descriptions of the system for MRI and its modules are for descriptive convenience only, and do not limit the present disclosure to the scope of the cited embodiments. It is to be understood that for those skilled in the art, after understanding the principle of the system, it may be possible to arbitrarily combine the individual modules or form a sub-system to be connected to the other modules without departing from the principle. In some embodiments, the obtaining module, the temporal information determination module, the spatial information determination module, and the motion correction module disclosed in FIG. 1 are different modules in a system, or a single module realizing functions of two or more of the above modules. For example, the individual modules share a common storage module, and the individual modules each has a respective storage module. Deformations such as these are within the scope of protection of the present disclosure.

The basic concepts have been described above, and it is apparent to those skilled in the art that the foregoing detailed disclosure serves only as an example and does not constitute a limitation of the present disclosure. While not expressly stated herein, those skilled in the art may make various modifications, improvements, and amendments to the present disclosure. Those types of modifications, improvements, and amendments are suggested in the present disclosure, so those types of modifications, improvements, and amendments remain within the spirit and scope of the exemplary embodiments of the present disclosure.

Also, the present disclosure uses specific words to describe embodiments of the specification, such as “an embodiment”, “one embodiment”, and/or “some embodiments” means a feature, structure, or characteristic associated with at least one embodiment of the present disclosure. Accordingly, it should be emphasized and noted that “one embodiment”, “an embodiment”, or “a number of embodiments” referred to two or more times in different positions in the present disclosure means a feature, structure, or characteristic related to at least one embodiment of the present disclosure. In addition, certain features, structures, or characteristics of one or more embodiments of the present disclosure are suitably combined.

Furthermore, unless expressly stated in the claims, the order of the processing elements and sequences, the use of numerical letters, or the use of other names as described in the present disclosure are not intended to qualify the order of the processes and methods of the present disclosure. While some embodiments of the invention that are currently considered useful are discussed in the foregoing disclosure by way of various examples, it is to be understood that such details serve only illustrative purposes and that additional claims are not limited to the disclosed embodiments. Rather, the claims are intended to cover all amendments and equivalent combinations that are consistent with the substance and scope of the embodiments of the present disclosure. For example, although the implementation of various components described above may be embodied in a hardware device, it may also be implemented as a software only solution, e.g., an installation on an existing server or mobile device.

Similarly, it should be noted that in order to simplify the presentation of the disclosure of the present disclosure, and thereby aid in the understanding of one or more embodiments thereof, the foregoing descriptions of embodiments of the present disclosure sometimes group multiple features together in a single embodiment, accompanying drawings, or a description thereof. However, this method of disclosure does not imply that the objects of the present disclosure require more features than those mentioned in the claims. Rather, claimed subject matter may lie in less than all features of a single foregoing disclosed embodiment.

Some embodiments use numbers to describe the number of components, attributes, and it should be understood that such numbers used in the description of the embodiments are modified in some examples by the modifiers “about”, “approximately”, or “substantially”. Unless otherwise noted, the terms “about,” “approximately,” or “substantially” indicates that a ±20% variation in the stated number is allowed. Correspondingly, in some embodiments, the numerical parameters used in the present disclosure and the claims are approximations, which change depending on the desired characteristics of individual embodiments. In some embodiments, the numerical parameters should consider the specified number of valid digits and use a general digit retention method. While the numerical domains and parameters used to confirm the breadth of their ranges in some embodiments of the present disclosure are approximations, in specific embodiments such values are set to be as precise as possible within a feasible range.

For each patent, patent application, patent application disclosure, and other material cited in the present disclosure, such as articles, books, manuals, publications, documents, etc., the entire contents of which are hereby incorporated herein by reference. Application history documents that are inconsistent with or conflict with the contents of the present disclosure are excluded, as are documents (currently or hereafter appended to the present disclosure) that limit the broadest scope of the claims of the present disclosure. It should be noted that in the event of any inconsistency or conflict between the descriptions, definitions, and/or use of terms in the materials appended to the present disclosure and those set forth herein, the descriptions, definitions and/or use of terms in the present disclosure shall prevail.

Finally, it should be understood that the embodiments described in the present disclosure are only used to illustrate the principles of the embodiments of the present disclosure. Other deformations may also fall within the scope of the present disclosure. As such, alternative configurations of embodiments of the present disclosure may be viewed as consistent with the teachings of the present disclosure as an example, not as a limitation. Correspondingly, the embodiments of the present disclosure are not limited to the embodiments expressly presented and described herein.

What is claimed is:

1. A method for magnetic resonance imaging comprising:
obtaining preliminary scanning data and navigation data of an imaging region of an imaging target;
determining, based on the navigation data, temporal information relating to at least one temporal dimension of the imaging region;
determining, based on the preliminary scanning data and the temporal information, spatial information relating to at least one spatial dimension of the imaging region; and
performing, based on the temporal information and the spatial information, a motion correction.

2. The method of claim 1, wherein the obtaining navigation data includes:
determining a collection period for collecting the navigation data; and
obtaining the navigation data from a magnetic resonance signal based on the collection period, or
extracting the navigation data from at least a portion of the preliminary scanning data.

3. The method of claim 1, wherein the determining, based on the preliminary scanning data and the temporal information, spatial information relating to at least one spatial dimension of the imaging region includes:
establishing, based on the temporal information, spatial information to be solved, and the preliminary scanning data, a first optimization model; and
determining the spatial information relating to at least one spatial dimension of the imaging region by minimizing a value of the first optimization model.

4. The method of claim 1, wherein the performing, based on the temporal information and the spatial information, a motion correction includes:
dividing the preliminary scanning data into a plurality of scanning data groups, each of the plurality of scanning data groups corresponding to a motion stage of a physiological motion of the imaging target; and
determining, based on the temporal information, the spatial information, and the plurality of scanning data groups, a deformation field of the preliminary scanning data.

5. The method of claim 4, wherein the deformation field of the preliminary scanning data includes a motion deformation field of each of the plurality of scanning data groups; and
the determining, based on the temporal information, the spatial information, and the plurality of scanning data groups, a deformation field of the preliminary scanning data includes:
for each of the plurality of scanning data groups,
determining the temporal information under the motion stage corresponding to the scanning data group;
determining, based on the spatial information and the temporal information corresponding the motion stage, a preliminary image of the motion stage; and
determining, based on the preliminary image of the motion stage, the motion deformation field of the scanning data group.

6. The method of claim 5, wherein the determining, based on the preliminary image of the motion stage, the motion deformation field of the scanning data group includes:
determining the motion deformation field for each of the plurality of scanning data groups by inputting the preliminary images of the plurality of scanning data groups into a first neural network.

7. The method of claim 4, further comprising:
generating, based on the preliminary scanning data and the deformation field of the preliminary scanning data, a reconstructed image.

8. The method of claim 7, wherein the generating, based on the preliminary scanning data and the deformation field of the preliminary scanning data, the reconstructed image includes:
establishing, based on the deformation field, a reconstruction image to be solved, and the preliminary scanning data, a second optimization model; and
determining the reconstruction image by minimizing a value of the second optimization model.

9. The method of claim 8, wherein the second constraint factor is obtained by constructing a regularization term based on a temporal direction.

10. The method of claim 1, wherein the performing, based on the temporal information and the spatial information, a motion correction includes:
determining corrected scanning data by performing, based on the temporal information and the spatial information, a motion correction on the preliminary scanning data.

11. The method of claim 10, wherein the determining corrected scanning data by performing, based on the temporal information and the spatial information, a motion correction on the preliminary scanning data includes:
determining the corrected scanning data by inputting the preliminary scanning data, the temporal information, and the spatial information into a second neural network for motion correction.

12. The method of claim 11, wherein the second neural network is trained by:
obtaining training data, the training data including training samples and corresponding labels; the training samples including sample preliminary scanning data, sample temporal information and sample spatial information, and the labels including label correction scanning data.

13. The method of claim 12, wherein the obtaining training data includes:
obtaining a first magnetic resonance signal collected from a sample object in a free breathing stage;
obtaining, based on the first magnetic resonance signal, the sample preliminary scanning data;
obtaining the sample temporal information and the sample spatial information based on the sample preliminary scanning data;
obtaining a second magnetic resonance signal collected from the sample object in a breath-holding state; and
obtaining, based on the second magnetic resonance signal, the label correction scanning data.

14. The method of claim 12, wherein the obtaining training data includes:
obtaining the sample preliminary scanning data, the sample temporal information, and the sample spatial information;
obtaining a deformation field based on the sample temporal information, and the sample spatial information; and
obtaining label correction scanning data by correcting the sample preliminary scanning data based on the deformation field.

15. The method of claim 10, further comprising:
establishing a third optimization model based on a reconstruction image to be solved and the corrected scanning data; and
determining a reconstructed image by minimizing a value of the third optimization model.

16. A system for magnetic resonance imaging comprising:
at least one storage device including a set of instructions; and
at least one processor in communication with the at least one storage device, wherein when executing the set of instructions, the at least one processor is directed to perform operations including:
obtaining preliminary scanning data and navigation data of an imaging region of an imaging target;
determining, based on the navigation data, temporal information relating to at least one temporal dimension of the imaging region;
determining, based on the preliminary scanning data and the temporal information, spatial information relating to at least one spatial dimension of the imaging region; and
performing, based on the temporal information and the spatial information, a motion correction.

17. The system of claim 16, wherein the performing, based on the temporal information and the spatial information, a motion correction includes:
dividing the preliminary scanning data into a plurality of scanning data groups, each of the plurality of scanning data groups corresponding to a motion stage of a physiological motion of the imaging target; and
determining, based on the temporal information, the spatial information, and the plurality of scanning data groups, a deformation field of the preliminary scanning data.

18. The system of claim 16, wherein the performing, based on the temporal information and the spatial information, a motion correction includes:
determining corrected scanning data by performing, based on the temporal information and the spatial information, a motion correction on the preliminary scanning data.

19. A method for magnetic resonance imaging comprising:
obtaining preliminary scanning data of an imaging region of an imaging target;
determining temporal information relating to at least one temporal dimension of the imaging region and spatial information relating to at least one spatial dimension of the imaging region; and
performing, based on the preliminary scanning data, the temporal information, and the spatial information, a motion correction.

20. The method of claim 19, wherein
the determining temporal information relating to at least one temporal dimension of the imaging region and spatial information relating to at least one spatial dimension of the imaging region includes:
obtaining navigation data of the imaging region of the imaging target;
determining, based on the navigation data, the temporal information; and
determining, based on the preliminary scanning data and the temporal information, the spatial information; and
the method further comprises:
generating a reconstructed image based on the motion correction.
